(19) United States
(12) Patent Application Publication
(10) Pub. No.: US 2025/0138432 A1
(43) Pub. Date: May 1, 2025

(54) Bottom-Up Main Pole Electroplating For A Magnetic Recording Write Head

(71) Applicant: Headway Technologies, Inc., Milpitas, CA (US)

(72) Inventors: Cherng-Chyi Han, San Jose, CA (US); Feiyue Li, Newark, CA (US); Weihao Xu, San Jose, CA (US); Weisheng Hu, Fremont, CA (US); Chaokang Gu, San Jose, CA (US); Ittetsu Kitajima, Cupertino, CA (US); Kaiyang Niu, Fremont, CA (US)

(21) Appl. No.: 18/384,545

(22) Filed: Oct. 27, 2023

(51) Int. Cl. G03F 7/00; C25D 5/02; C25D 5/34; G11B 5/39

(52) U.S. Cl. CPC G03F 7/7045; C25D 5/022; C25D 5/34; G11B 5/3906

(57) ABSTRACT

The present embodiments relate to MP electroplating processes that eliminate seamlines using a bottom-up MP electroplating process. The MP electroplating process can include, after disposing the side shield, depositing a Ru layer as a side gap layer. The process can further include depositing an insulator layer. The MP bottom-up electroplating process can further include performing an ion-beam-etch (IBE) process to clean the insulator at bottom of the trench. After resist patterning, the electroplating process can include electroplating the MP on Ru seed only from the bottom of the trench. The seamline in the MP can be eliminated in the bottom-up MP electroplating process.

### TECHNICAL FIELD

Embodiments of the invention relate to the field of perpendicular magnetic recording (PMR) write heads for a hard disk drive (HDD). More particularly, embodiments of the invention relate to manufacturing a write head using a bottom-up main pole electroplating process.

### BACKGROUND

Volumes of digital data can be stored on a disk drive, such as a Hard disk drive (HDD). The disk drive can comprise a head that can interact with a magnetic recording medium (e.g., a disk) to read and write magnetic data onto the disk. For instance, the disk drive can include a write head that is positioned near the disk and can modify a magnetization of the disk passing immediately under the write head.

Disk drives can utilize various technologies to write to a disk. For example, perpendicular magnetic recording (PMR) can relate to magnetic bits on a disk are directed perpendicular (e.g., either up or down) relative to the disk surface. PMR recording can increase storage density to the disk by aligning poles of magnetic elements on the disk perpendicularly to the surface of the disk.

### SUMMARY

The present embodiments relate to MP electroplating processes that eliminate seamlines using a bottom-up MP electroplating process. The MP electroplating process can include, after disposing the side shield, depositing a Ru layer as a side gap layer. The process can further include depositing an insulator layer. The MP bottom-up electroplating process can further include performing an ion-beam-etch (IBE) process to clean the insulator at bottom of the trench. After resist patterning, the electroplating process can include electroplating the MP on Ru seed only from the bottom of the trench. The seamline in the MP can be eliminated in the bottom-up MP electroplating process.

In a first example embodiment, a method for manufacturing a perpendicular magnetic recording (PMR) write head is provided. The method can include disposing a metallic layer over a side shield. A trench can be formed in the side shield. In some instances, the metallic layer comprises Ruthenium (Ru). In some instances, a thickness of the metallic layer is between 200-400 A.

The method can also include disposing an insulator layer over the metallic layer. In some instances, a thickness of the insulator layer ranges between 50-150 Angstroms (A). In some instances, the insulator layer comprises any of aluminum oxide (Al2O3), silicon dioxide (SiO2), and tantalum pentoxide (Ta2O5). In some instances, after the depositing of the insulator layer, a thickness of a portion of the insulator layer at the bottom of the trench is either equal to or less than a thickness of another portion of the insulator layer along one or more walls of the trench.

The method can also include performing an ion beam etching (IBE) process to remove at least a portion of the insulator layer at a bottom of the trench. In some instances, the IBE process is a 0-degree IBE process, and the portion of the insulator layer along the walls of the trench is etched either equal to or less than an amount of the insulator layer etched at the bottom of the trench. The 0-degree IBE can remove a same amount of the insulator layer at a bottom and along the walls of the trench. In some instances, some remaining insulator layer can remain along the walls of the trench at least due to the deposited insulator layer on the slanted walls being thicker if measured in a direction not perpendicular to the wall but not due to less etch amounts as compared to that at the bottom of the trench.

The method can also include disposing a photo resist over at least a portion of the insulator layer. The method can also include patterning the photo resist.

The method can also include electroplating a main pole at least in the trench. In some instances, the method can include stripping the photo resist. Further, the etched insulator layer and metallic layer can planarize the side shield and the main pole.

In another example embodiment, a method is provided. The method can include disposing a Ruthenium (Ru) layer over a side shield. A trench can be formed in the side shield. In some instances, a thickness of the Ru layer is between 200-400 A.

The method can also include disposing an oxide insulator layer over the Ru layer. In some instances, a thickness of the oxide insulator layer ranges between 50-150 Angstroms (A). In some instances, the oxide insulator layer comprises any of aluminum oxide (Al2O3), silicon dioxide (SiO2), and tantalum pentoxide (Ta2O5).

In some instances, after the depositing of the insulator layer, a thickness of a portion of the insulator layer at the bottom of the trench is either equal to or less than a thickness of another portion of the insulator layer along one or more walls of the trench.

The method can also include performing an etching process to remove at least a portion of the insulator layer at a bottom of the trench. In some instances, the etching process is an ion beam etching (IBE) process, and the portion of the insulator layer along the walls of the trench is etched either equal to or less than an amount of the insulator layer etched at the bottom of the trench.

The method can also include disposing a photo resist over at least a portion of the insulator layer. The method can also include patterning the photo resist. The method can also include electroplating a main pole at least in the trench. The method can also include stripping the photo resist.

Other features and advantages of embodiments of the present invention will be apparent from the accompanying drawings and from the detailed description that follows.

### BRIEF DESCRIPTION OF THE DRAWINGS

Embodiments of the present invention are illustrated by way of example and not

limitation in the figures of the accompanying drawings, in which like references indicate similar elements and in which:

FIG. 1 is a perspective view of a head arm assembly, according to prior art embodiments.

FIG. 2 is side view of a head stack assembly, according to prior art embodiments.

FIG. 3 is a plan view of a magnetic recording apparatus, according to prior art embodiments.

FIG. 4 is a down-track cross-sectional view of a combined read-write head with

complete trailing and leading magnetic flux return loops, according to prior art embodiments.

FIG. 5 is a down-track cross-sectional view of a PMR writer having a uDY design for the trailing loop and a rDWS BGC layout for the leading loop, according to prior art embodiments.

FIG. 6 is an example prior art write head with a seamline defined in the main pole.

FIG. 7 is a first view of a write head generated via a bottom-up MP electroplating process, according to embodiments of the present disclosure.

FIG. 8 is a second view of a write head generated via a bottom-up MP electroplating process, according to embodiments of the present disclosure.

FIG. 9 is a third view of a write head generated via a bottom-up MP electroplating process, according to embodiments of the present disclosure.

### DETAILED DESCRIPTION

Disk drives can utilize various technologies to write to a disk. For example, perpendicular magnetic recording (PMR) can relate to magnetic bits on a disk are directed perpendicular (e.g., either up or down) relative to the disk surface. PMR recording can increase storage density to the disk by aligning poles of magnetic elements on the disk perpendicularly to the surface of the disk.

Further, a disk drive head can include a main pole (MP) with a tip portion configured to be disposed near the surface of the disk. The distance between the main pole tip portion and the disk can be controlled by a dynamic fly height (DFH) writer heater. Particularly, DFH writer heater can heat a portion of the head, causing the MP to expand or contract, thereby modifying the distance between the main pole tip portion and the disk. Electrical energy can be provided to any of the DFH writer heater and the MP tip portion via electrical pads, forming a circuit in the head.

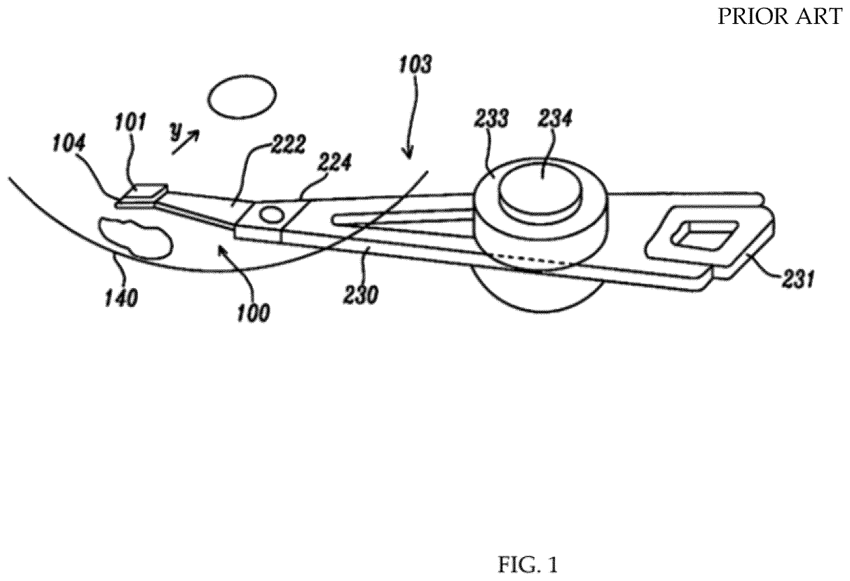

FIG. 1 is a perspective view of a head arm assembly 100, according to some embodiments of the present disclosure. Referring to FIG. 1, a head arm assembly (or Head Gimbal Assembly (HGA)) 100 includes a magnetic recording head 101 comprised of a slider and a PMR writer structure formed thereon, and a suspension 103 that elastically supports the magnetic recording head. The suspension has a plate spring-like load beam 222 formed with stainless steel, a flexure 104 provided at one end portion of the load beam, and a base plate 224 provided at the other end portion of the load beam. The slider portion of the magnetic recording head is joined to the flexure, which gives an appropriate degree of freedom to the magnetic recording head. A gimbal part (not shown) for maintaining a posture of the magnetic recording head at a steady level is provided in a portion of the flexure to which the slider is mounted.

HGA 100 is mounted on an arm 230 formed in the head arm assembly 103. The arm moves the magnetic recording head 101 in the cross-track direction y of the magnetic recording medium 140. One end of the arm is mounted on base plate 224. A coil 231 that is a portion of a voice coil motor is mounted on the other end of the arm. A bearing part 233 is provided in the intermediate portion of arm 230. The arm is rotatably supported using a shaft 234 mounted to the bearing part 233. The arm 230 and the voice coil motor that drives the arm configure an actuator.

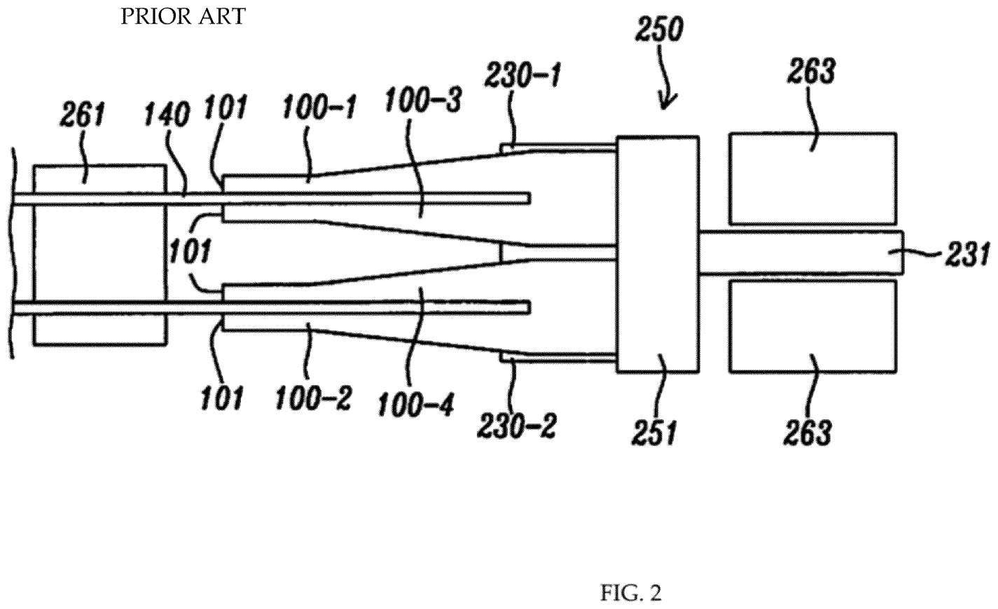

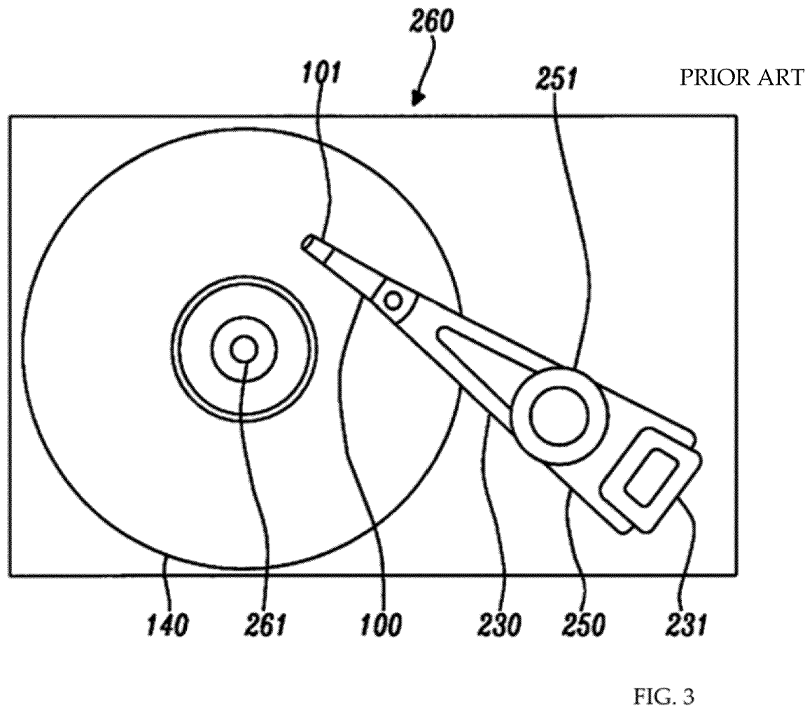

Next, a side view of a head stack assembly (FIG. 2) and a plan view of a magnetic recording apparatus (FIG. 3) wherein the magnetic recording head 101 is incorporated are depicted. The head stack assembly 250 is a member to which a plurality of HGAs (HGA 100-1 and second HGA 100-2 are at outer positions while HGA 100-3 and HGA 100-4 are at inner positions) is mounted to arms 230-1, 230-2, respectively, on carriage 251. A HGA is mounted on each arm at intervals so as to be aligned in the perpendicular direction (orthogonal to magnetic medium 140). The coil portion (231 in FIG. 1) of the voice coil motor is mounted at the opposite side of each arm in carriage 251. The voice coil motor has a permanent magnet 263 arranged at an opposite position across the coil 231.

With reference to FIG. 3, the head stack assembly 250 is incorporated in a magnetic recording apparatus 260. The magnetic recording apparatus has a plurality of magnetic media 140 mounted to spindle motor 261. For every magnetic recording medium, there are two magnetic recording heads arranged opposite one another across the magnetic recording medium. The head stack assembly and actuator except for the magnetic recording heads 101 correspond to a positioning device, and support the magnetic recording heads, and position the magnetic recording heads relative to the magnetic recording medium. The magnetic recording heads are moved in a cross-track of the magnetic recording medium by the actuator. The magnetic recording head records information into the magnetic recording media with a PMR writer element (not shown) and reproduces the information recorded in the magnetic recording media by a magneto-resistive (MR) sensor element (not shown).

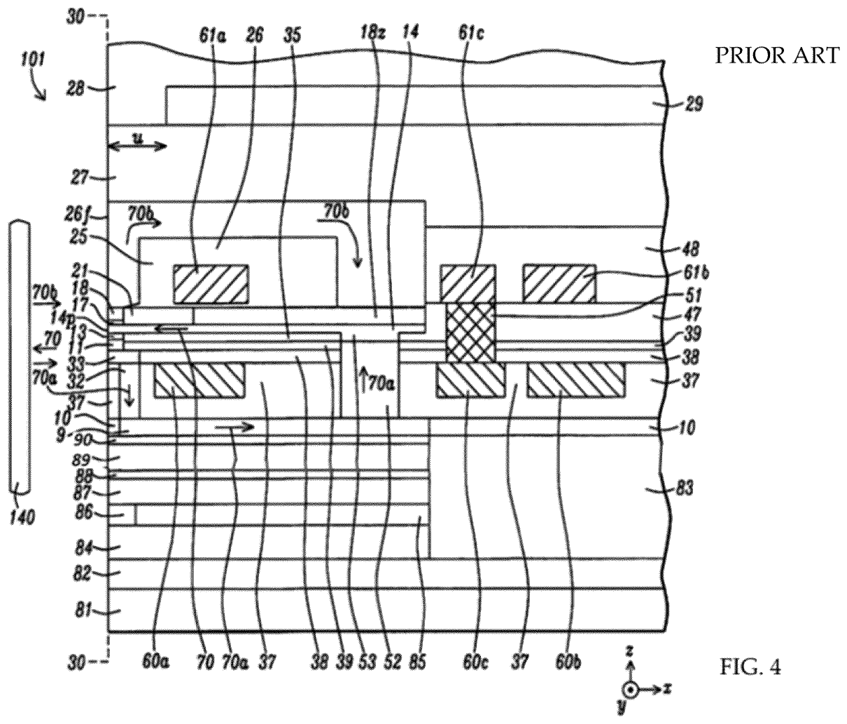

Referring to FIG. 4, magnetic recording head 101 comprises a combined read-write head. The down-track cross-sectional view is taken along a center plane formed orthogonal to the ABS 30-30, and that bisects MP 14. The read head is formed on a substrate 81 that may be comprised of AlTiC (alumina+TiC) with an overlying insulation layer 82 that is made of a dielectric material such as alumina. The substrate is typically part of a slider formed in an array of sliders on a wafer. After the combined read head/write head is fabricated, the wafer is sliced to form rows of sliders. Each row is typically lapped to afford an ABS before dicing to fabricate individual sliders that are used in a magnetic recording device. A bottom shield 84 is formed on insulation layer 82.

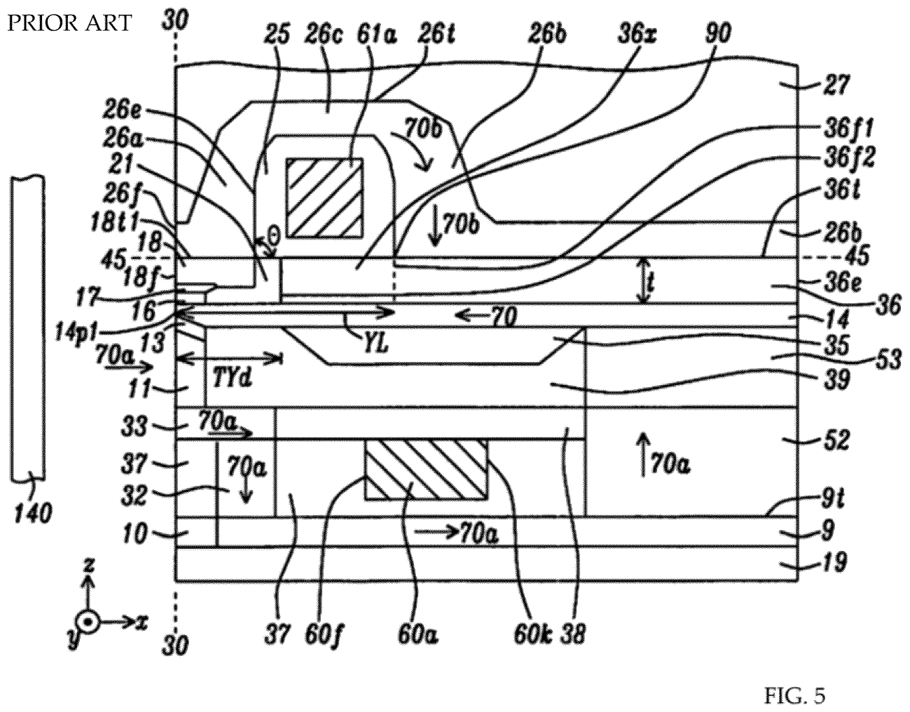

A magneto resistive (MR) element also known as MR sensor 86 is formed on bottom shield 84 at the ABS 30-30 and typically includes a plurality of layers (not shown) including a tunnel barrier formed between a pinned layer and a free layer where the free layer has a magnetization (not shown) that rotates in the presence of an applied magnetic field to a position that is parallel or antiparallel to the pinned layer magnetization. Insulation layer 85 adjoins the backside of the MR sensor, and insulation layer 83 contacts the backsides of the bottom shield and top shield 87. The top shield is formed on the MR sensor. An insulation layer 88 and a second top shield (S2B) layer 89 and an insulation layer 90 are sequentially formed on the top magnetic shield. Note that layer 9 may be a non-magnetic layer such as an AlOx layer or a magnetic layer served as a flux return path (RTP) in the write head portion of the combined read/write head. Thus, the portion of the combined read/write head structure formed below layer 9 in FIG. 5 is typically considered as the read head. In other embodiments (not shown), the read head may have a dual reader design with two MR sensors, or a multiple reader design with multiple MR sensors.

Various configurations of a write head may be employed with the read head portion. In some embodiments, magnetic flux 70 in MP 14 is generated with flowing a current through bucking coil 60 a-c and driving coil 61 a-c where front portions 60 a and 61 a are below and above the MP, respectively, center portions 60 c and 61 c are connected by interconnect 51, and back portions 60 b and 61 b are connected to writer pads (not shown). Magnetic flux 70 exits the MP at pole tip 14 p at the ABS 30-30 and is used to write a plurality of bits on magnetic media 140. Magnetic flux 70b returns to the MP through a trailing loop comprised of a trailing shield structure including HS layer 17, WS 18, and uppermost trailing (PP3) shield 26, and top yoke 18 x. There is also a leading loop with a recessed DWS (rDWS) BGC layout for magnetic flux 70 a return to the MP where LSC 32 and RTP 9 are recessed from the ABS 30-30. The rDWS BGC design features leading shield (LS) 11, leading shield connector (LSC) 33, S2 connector (S2C) 32, return path (RTP) 9, lower back gap (LBG) 52, and back gap connection (BGC) 53. In another embodiment (not shown), only the LS is retained in the leading return loop in a so-called non-dual write shield (nDWS) scheme where the LSC, S2C, RTP, LBG, and BGC are omitted to enhance magnetic flux in the trailing loop. The magnetic core may also comprise a bottom yoke 35 below the MP.

Dielectric layers 10, 13, 21, 37-39, and 47-48 are employed as insulation layers around magnetic and electrical components. A protection layer 27 covers the PP3 shield and is made of an insulating material such as alumina. Above the protection layer and recessed a certain distance u from the ABS 30-30 is an optional cover layer 29 that is preferably comprised of a low coefficient of thermal expansion (CTE) material such as SiC. Overcoat layer 28 is formed as the uppermost layer in the write head.

Typically, a dynamic fly height (DFH) heater (not shown) is formed in one or more insulation (dielectric) layers in each of the read head and write head to control the extent of thermal expansion (protrusion) at the ABS and toward a magnetic medium during a read process and write process, respectively. Read gap (RG) and write gap (WG) protrusion may be tuned by the placement of the DFH heaters, and by the choice of metal or alloy selected for the DFH heaters since each DFH heater is comprised of a resistor material with a particular thermal and mechanical response to a given electrical input.

Referring to FIG. 5, an enlargement of a write head portion of a combined read-write head is shown according to some embodiments. A uDY rDWS BGC base writer design is shown where the trailing loop has an ultimate double yoke (uDY) scheme, and the leading loop has a rDWS BGC layout. Bucking coil front portion 60 a has front side 60 f that is recessed from the ABS 30-30, backside 60 k facing LBG 52, and is formed in insulation layer 37 and above RTP top surface 9 t. RTP 9 is formed on bottommost insulation layer 19. Leading shield (LS) 11 contacts a top surface of LS connector (LSC) 33 at the ABS. Insulation layer 38 adjoins a backside of the LSC and extends to a BGC front side. The leading loop for flux return 70 a continues from the LS and LSC through S2C 32 and the RTP before passing upward through the lower back gap (LBG) 52 and BGC 53. The BGC contacts a bottom surface of MP 14 behind tapered bottom yoke (tBY) 35. Insulation layer 39 extends from the LS backside to the BGC front side and contacts a top surface of insulation layer 38. The tBY 35 is formed within insulation layer 39, and between the LS and BGC.

The trailing loop comprises HS layer 17, WS 18 with front side 18 f at the ABS 30-30, PP3 TS 26 that has front side 26 f at the ABS, and TY 36 with top surface 36 t adjoining the PP3 TS behind driving coil (DC) 61 a so that magnetic flux 70 b from magnetic medium 140 is able to return to MP 14. DC 61 a is formed above insulation layer 21 and is surrounded on the sides and top and bottom surfaces with insulation layer 25. PP3 TS top surface 26 t arches (dome shape) over DC front portion 61 a. Protection layer 27 covers the PP3 TS and is made of an insulating material such as alumina. Note that the TY has a thickness t, and height d between a front side 36 f 1 and backside 36 e where the front side is directly below the inner corner 90 of the PP3 TS where the PP3 TS contacts plane 45-45. The uDY aspect of the trailing loop is related to the feature where the TY is comprised of a TY extension 36 x having a front side 36 f 2 that is recessed a distance TYd of 0.8 to 1.3 microns from ABS 30-30, and a backside that interfaces with TY front side 36 f 1. Yoke length (YL) is defined as the distance between the ABS and TY front side 36 f 1. The TY extension has a thickness t of 0.3-0.8 microns, which is equal to that of TY 36. The PP3 TS has a middle portion 26 c with a dome shaped top surface 26 t formed above driving coil front portion 61 a. A front portion 26 a of the PP3 TS is formed on WS 18 and has an inner side 26 e that forms an apex angle θ, preferably from 60 degrees to 80 degrees, with respect to plane 45-45 that comprises TY top surface 36 t and is orthogonal to the ABS. A back portion 26 b of the PP3 TS adjoins a top surface of TY 36. The PP3 TS apex angle is believed to enhance flux concentration at WS 18 and provides improved high data rate performance. A key feature is that TYd is less than YL. Driving coil front portion 61 a is entirely above plane 45-45 and TY extension 36 x, and within insulation layer 25.

Leading shield 11, LSB 33, S2C 32, LBG 52, BGC 53, and RTP 9 are generally made of NiFe, NiFeRe, CoFe, CoFeN, CoFeNi or the like with a saturation magnetization (Ms) value of 4 kiloGauss (KG) to 16 kG. WS 18, PP3 TS 26 a-26 c, TY 36, and TY extension 36 x are typically made of NiFe, NiFeRe, CoFe, CoFeNi, or CoFeN having a Ms 10 kG to 19 KG while HS layer 17 and MP 14 have a Ms from 19 kG to 24 KG. In this scheme, the tBY 35 contacts a bottom surface of MP 14 below the TY extension. Although the PP3 TS 26 a-c has a front side 26 f at the ABS, the front side may be recessed from the ABS 30-30 in other embodiments (not shown).

In many instances, a seamline can be present within the main pole body at the ABS. This seam line can be due at least in part to growth of the main pole film from seeds on both side walls of a trench defined in the side shield plating in many perpendicular magnetic recording (PMR) magnetic recording structures and designs.

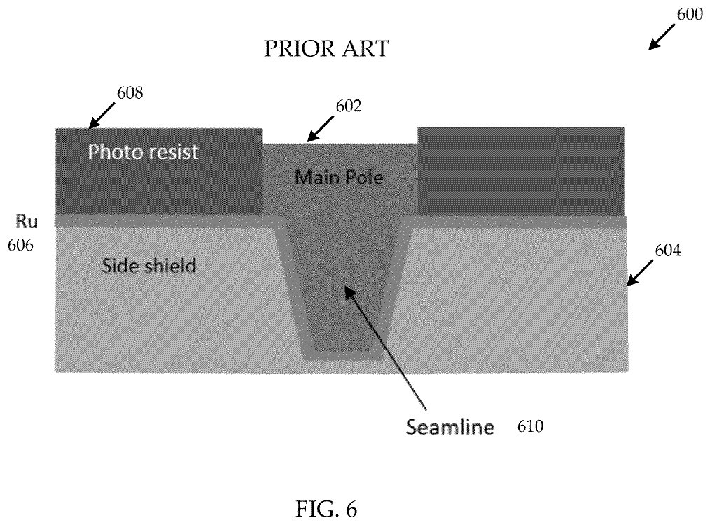

FIG. 6 is an example prior art write head with a seamline defined in the main pole. As shown in FIG. 6, the write head 600 can include a main pole 602, a side shield (SS) 604, and a Ru layer 606 disposed between the SS 604 and main pole 602. Further, a photoresist 608 can be disposed on one or more sides of the main pole 602 and in contact with the Ru layer 606.

The main pole 602 can further include a seamline 610 The seamline can be less dense than main pole body, and its composition can be different from the body. These features can cause a magnetic moment reduction in main pole volume.

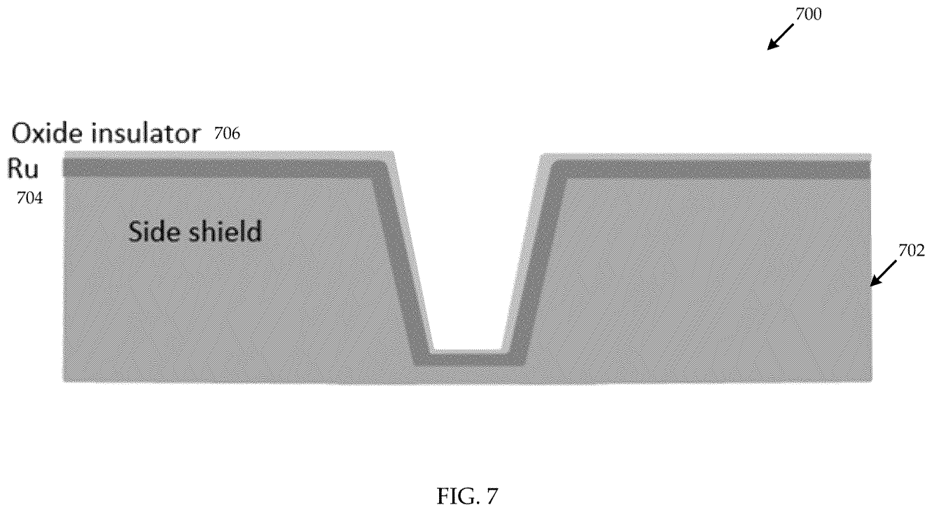

The present embodiments relate to MP electroplating processes that eliminate such seamlines using a bottom-up MP electroplating process. The MP electroplating process can include, after disposing the side shield, depositing a 200˜400 Angstrom (A) Ru layer as a side gap layer. The process can further include depositing a 50˜150 A insulator. The insulator can include materials such as Al2O3, SiO2, Ta2O5, etc. Further, the insulator thickness can be thinner at bottom than on the walls (e.g., as shown in FIG. 7).

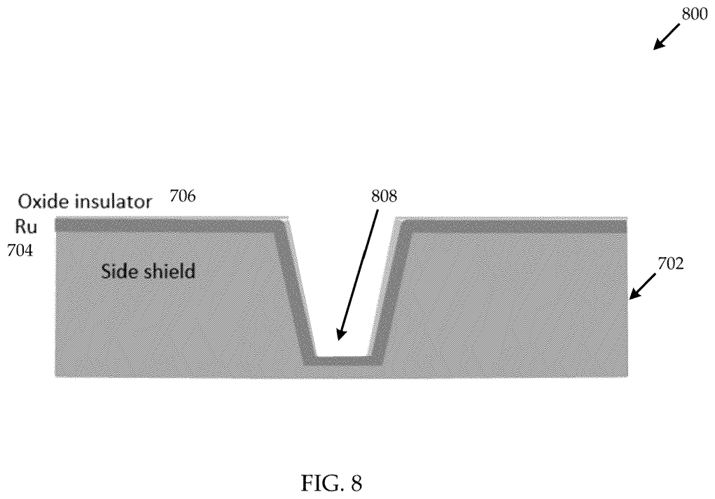

The MP bottom-up electroplating process can further include performing a 0-degree ion-beam-etch (IBE) process to clean the insulator at bottom of the trench. In this process, the insulators on the walls can be etched less because the deposited oxide on the walls can be thicker than that at the bottom of trench (e.g., as shown in FIG. 8).

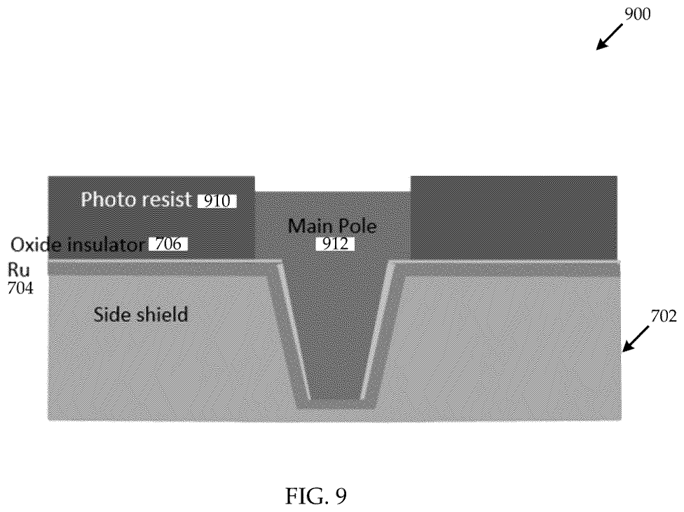

After resist patterning, the electroplating process can include electroplating the MP on Ru seed only from the bottom of the trench. The Ru seeds on the walls can be insulated by the oxides as mentioned above. The seamline in MP can be eliminated in this bottom-up MP electroplating (e.g., as shown in FIG. 9). After stripping the resist, the seed layer IBE, and MP CMP can planarize the side shield and MP surface.

The bottom-up MP electroplating process can include partially or completely remove seamline in MP w/a dense MP body. This can increase magnetic moments in MP volume to improve the head OW.

FIG. 7 is a first view of a write head 700 generated via a bottom-up MP electroplating process. As shown in FIG. 7, a Ru layer 704 can be disposed above a side shield 702. Further, an oxide insulator 706 can be disposed above the Ru layer 704. The side shield trench, Ru side gap and oxide insulator can be deposited on a top, sidewall, and bottom of the side shield trench.

FIG. 8 is a second view of a write head 800 generated via a bottom-up MP electroplating process. As shown in FIG. 8, a portion of the oxide layer (e.g., portion 808) at a bottom of a trench of the side shield can be removed via an ion beam etching (IBE) process. Further, oxides outside the trench and on the walls can be thinned down after the IBE process.

FIG. 9 is a third view of a write head 900 generated via a bottom-up MP electroplating process. As shown in FIG. 9, a photo resist 910 can be patterned over the oxide layer 706. Further, a main pole 912 can be electroplated over the oxide insulator 706 and in the trench formed by the side shield 702.

In a first example embodiment, a method for manufacturing a perpendicular magnetic recording (PMR) write head is provided. The method can include disposing a metallic layer over a side shield. A trench can be formed in the side shield. In some instances, the metallic layer comprises Ruthenium (Ru). In some instances, a thickness of the metallic layer is between 200-400 A.

The method can also include disposing an insulator layer over the metallic layer. In some instances, a thickness of the insulator layer ranges between 50-150 Angstroms (A). In some instances, the insulator layer comprises any of aluminum oxide (Al2O3), silicon dioxide (SiO2), and tantalum pentoxide (Ta2O5). In some instances, after the depositing of the insulator layer, a thickness of a portion of the insulator layer at the bottom of the trench is less than or equal to a thickness of another portion of the insulator layer along one or more walls of the trench.

The method can also include performing an ion beam etching (IBE) process to remove at least a portion of the insulator layer at a bottom of the trench. In some instances, the IBE process is a 0-degree IBE process. The portion of the insulator layer along the walls of the trench is etched at either the same or less than an amount of the insulator layer etched at the bottom of the trench. The 0-degree IBE can remove a same amount of the insulator layer at a bottom and along the walls of the trench. In some instances, some remaining insulator layer can remain along the walls of the trench at least due to the deposited insulator layer on the slanted walls being thicker if measured in a direction not perpendicular to the wall but not due to less etch amounts as compared to that at the bottom of the trench.

The method can also include disposing a photo resist over at least a portion of the insulator layer. The method can also include patterning the photo resist.

The method can also include electroplating a main pole at least in the trench. In some instances, the method can include stripping the photo resist. Further, the etched insulator layer and metallic layer can planarize the side shield and the main pole.

In another example embodiment, a method is provided. The method can include disposing a Ruthenium (Ru) layer over a side shield. A trench can be formed in the side shield. In some instances, a thickness of the Ru layer is between 200-400 A.

The method can also include disposing an oxide insulator layer over the Ru layer. In some instances, a thickness of the oxide insulator layer ranges between 50-150 Angstroms (A). In some instances, the oxide insulator layer comprises any of aluminum oxide (Al2O3), silicon dioxide (SiO2), and tantalum pentoxide (Ta2O5).

In some instances, after the depositing of the insulator layer, a thickness of a portion of the insulator layer at the bottom of the trench is either equal to or less than a thickness of another portion of the insulator layer along one or more walls of the trench.

The method can also include performing an etching process to remove at least a portion of the insulator layer at a bottom of the trench. In some instances, the etching process is an ion beam etching (IBE) process, and the portion of the insulator layer along the walls of the trench is etched either equal to or less than an amount of the insulator layer etched at the bottom of the trench.

The method can also include disposing a photo resist over at least a portion of the insulator layer. The method can also include patterning the photo resist. The method can also include electroplating a main pole at least in the trench. The method can also include stripping the photo resist.

It will be understood that terms such as “top,” “bottom,” “above,” “below,” and x-direction, y-direction, and z-direction as used herein as terms of convenience that denote the spatial relationships of parts relative to each other rather than to any specific spatial or gravitational orientation. Thus, the terms are intended to encompass an assembly of component parts regardless of whether the assembly is oriented in the particular orientation shown in the drawings and described in the specification, upside down from that orientation, or any other rotational variation.

It will be appreciated that the term “present invention” as used herein should not be construed to mean that only a single invention having a single essential element or group of elements is presented. Similarly, it will also be appreciated that the term “present invention” encompasses a number of separate innovations, which can each be considered separate inventions. Although the present invention has been described in detail with regards to the preferred embodiments and drawings thereof, it should be apparent to those skilled in the art that various adaptations and modifications of embodiments of the present invention may be accomplished without departing from the spirit and the scope of the invention. Accordingly, it is to be understood that the detailed description and the accompanying drawings as set forth hereinabove are not intended to limit the breadth of the present invention, which should be inferred only from the following claims and their appropriately construed legal equivalents.

What is claimed is:

1. A method for manufacturing a perpendicular magnetic recording (PMR) write head, the method comprising:
disposing a metallic layer over a side shield, wherein a trench is formed in the side shield;
disposing an insulator layer over the metallic layer;
performing an ion beam etching (IBE) process to remove at least a portion of the insulator layer at a bottom of the trench;
disposing a photo resist over at least a portion of the insulator layer;
patterning the photo resist; and
electroplating a main pole at least in the trench.

2. The method of claim 1, wherein a thickness of the insulator layer ranges between 50-150 Angstroms (A).

3. The method of claim 1, wherein the insulator layer comprises any of aluminum oxide (Al2O3), silicon dioxide (SiO2), and tantalum pentoxide (Ta2O5).

4. The method of claim 1, wherein the metallic layer comprises Ruthenium (Ru).

5. The method of claim 1, wherein a thickness of the metallic layer is between 200-400 A.

6. The method of claim 1, wherein, after the depositing of the insulator layer, a thickness of a portion of the insulator layer at the bottom of the trench is either equal to or less than a thickness of another portion of the insulator layer along one or more walls of the trench.

7. The method of claim 6, wherein the IBE process is a 0-degree IBE process, and wherein the portion of the insulator layer along the walls of the trench is etched either equal to or less than an amount of the insulator layer etched at the bottom of the trench.

8. The method of claim 1, further comprising:
stripping the photo resist, wherein the etched insulator layer and metallic layer planarize the side shield and the main pole.

9. A method comprising:
disposing a Ruthenium (Ru) layer over a side shield, wherein a trench is formed in the side shield;
disposing an oxide insulator layer over the Ru layer;
performing an etching process to remove at least a portion of the insulator layer at a bottom of the trench;
disposing a photo resist over at least a portion of the insulator layer;
patterning the photo resist;
electroplating a main pole at least in the trench; and
stripping the photo resist.

10. The method of claim 9, wherein a thickness of the oxide insulator layer ranges between 50-150 Angstroms (A).

11. The method of claim 9, wherein the oxide insulator layer comprises any of aluminum oxide (Al2O3), silicon dioxide (SiO2), and tantalum pentoxide (Ta2O5).

12. The method of claim 9, wherein a thickness of the Ru layer is between 200-400 A.

13. The method of claim 9, wherein, after the depositing of the insulator layer, a thickness of a portion of the insulator layer at the bottom of the trench is either equal to or less than a thickness of another portion of the insulator layer along one or more walls of the trench.

14. The method of claim 13, wherein the etching process is an ion beam etching (IBE) process, and wherein the portion of the insulator layer along the walls of the trench is etched either equal to or less than an amount of the insulator layer etched at the bottom of the trench.
